(19) United States
(12) Patent Application Publication
(10) Pub. No.: US 2026/0202492 A1
(43) Pub. Date: Jul. 16, 2026

(54) DEVICE AND METHOD FOR DETECTING SURFACE WEAK MAGNETIC FIELDS BASED ON GIANT MAGNETO-IMPEDANCE EFFECT

(71) Applicant: Beijing Physcience Opto-electronics Co., Ltd., Beijing (CN)

(72) Inventors: Jun LU, Beijing (CN); Xuekui Xi, Beijing (CN); Guoqiang Li, Beijing (CN); Bocheng Yu, Beijing (CN)

(21) Appl. No.: 19/446,099

(22) Filed: Jan. 12, 2026

(30) Foreign Application Priority Data
Jan. 10, 2025 (CN) 202510044886.8

(51) Int. Cl. G01R 33/06; G01R 33/00; G01R 33/12

(52) U.S. Cl. CPC G01R 33/063; G01R 33/0017; G01R 33/1253

(57) ABSTRACT

The present disclosure relates to a device and method for detecting surface weak magnetic fields based on a giant magneto-impedance effect. A magnetic field measurement method comprises: positioning a giant magneto-impedance probe at a first position near a surface of an object to be measured; applying an AC current to the giant magneto-impedance probe and measuring a first AC voltage of the probe; calculating impedance based on the AC current and the first AC voltage, and determining a first magnetic field based on the impedance; positioning the giant magneto-impedance probe at a second position above the first position; applying the AC current to the giant magneto-impedance probe and measuring a second AC voltage of the probe; calculating impedance based on the AC current and the second AC voltage, and determining a second magnetic field based on the impedance; and calculating a measurement magnetic field at the first position based on the first magnetic field and the second magnetic field.

### TECHNICAL FIELD

The present disclosure is related generally to the field of magnetism, and more particularly to a device and method for detecting surface weak magnetic fields utilizing the giant magneto-impedance (GMI) effect.

### BACKGROUND

Magnetic detection technology is widely deployed in fields including storage, navigation, power transmission, household appliances, and industrial control. Diverse magnetic sensors leveraging distinct magnetic effects have been developed to address varied detection requirements. At present, commonly used magnetic sensors comprise Hall-effect sensors, anisotropic magnetoresistance (AMR) sensors, giant magnetoresistance (GMR) sensors, tunneling magnetoresistance (TMR) sensors, and giant magneto-impedance (GMI) sensors.

Unlike measuring spatial magnetic fields, a specific application scenario is to measure weak magnetic fields on a surface of an object, which is being required in fields such as materials science and anti-counterfeiting. Hall-effect sensors suffer from limited sensitivity, while AMR sensors require Wheatstone bridge configurations, neither of which is suitable for measuring weak magnetic fields on a surface of an object. GMR sensors and TMR sensors have high sensitivity, and the free magnetic layer used for measuring magnetic fields can be formed with a nanoscale thickness, making them suitable for measuring weak magnetic fields on a surface of an object. However, GMR sensors and TMR sensors have complex multilayer film structures that require tedious and complex semiconductor manufacturing processes, comprising thin film deposition, photolithography, etching, and vacuum annealing with magnetic fields. Thus, the manufacturing equipment is expensive, resulting in high costs. Although conventional GMI sensors have merits such as high sensitivity, small size, fast response speed, and low and limited power consumption, they detect the average magnetic field along the entire length of the solenoid coil, making them only suitable for measuring spatial magnetic fields and not weak magnetic fields on a surface of an object.

### SUMMARY

To overcome the above limitations, the present disclosure provides a device and method for detecting weak magnetic fields on a surface of an object based on a giant magneto-impedance effect. As mentioned above, the conventional GMI sensors measure the average magnetic field along the entire length of the solenoid coil, while the weak magnetic field on the surface of the object has a thin spatial distribution and will rapidly decay as a distance from the surface of the object increases. Therefore, it is not suitable to be measured by using GMI sensors for measurement through conventional methods. The present disclosure proposes a novel measurement means, which measures magnetic fields at two height positions on a surface of an object, and then calculates a difference between the two, to obtain a micro area magnetic field close to a position on the surface of the object. The present disclosure not only can utilize the advantages of high sensitivity and low cost of GMI sensors, but also eliminates system noise and environmental noise through this differential measurement manner, thereby enabling more accurate measurement of weak magnetic fields on the surface of the object.

The magnetic field detection device of the present disclosure according to another embodiment, on one hand, uses an alternating current signal of a first frequency to drive the GMI probe, and accurately extracts the amplitude of the alternating voltage signal of the first frequency provided by the GMI probe in the measurement circuit to generate a measurement signal indicating the amplitude; and on the other hand, it drives the vibrating head to vibrate at a second frequency. The magnetic field detection device further uses an interlock circuit to extract the amplitude of the measurement signal oscillating at the second frequency, and provides a reference signal of the second frequency to the vibration drive circuit, thereby achieving locking of the first frequency used by the measurement system and the second frequency used by the vibration system. In this way, the magnetic field detection device of the present disclosure can achieve high-speed and accurate magnetic field measurement. On another hand, the present disclosure further provides two GMI probes vertically arranged at different heights, which can be used to offset the influence of environmental magnetic fields (such as geomagnetism) on the magnetic field to be measured (i.e., the weak magnetic field on the surface of the object), thereby further improving measurement accuracy.

According to an embodiment, the present disclosure provides a magnetic field detection device, which may comprise: a giant magneto-impedance probe; an alternating current AC signal source configured to apply an AC current to the giant magneto-impedance probe; a measurement circuit configured to measure an AC voltage on the giant magneto-impedance probe; a calculation unit configured to calculate impedance based on the AC current and AC voltage, and determine a magnitude of the magnetic field based on the impedance; and a positioning unit configured to support the giant magneto-impedance probe and position the giant magneto-impedance probe to a predetermined position, wherein when the positioning unit positions the giant magneto-impedance probe at a first position near the surface of the object to be measured, the measurement circuit measures a first AC voltage of the giant magneto-impedance probe, and the calculation unit calculates a first magnetic field based on the first AC voltage; and when the positioning unit positions the giant magneto-impedance probe at a second position above the first position, the measurement circuit measures a second AC voltage of the giant magneto-impedance probe, and the calculation unit calculates a second magnetic field based on the second AC voltage, and calculates a measurement magnetic field at the first position near the surface of the object to be measured based on the first magnetic field and the second magnetic field.

According to an example, the positioning unit positions the giant magneto-impedance probe perpendicular to the surface of the object to be measured, and the second position is located vertically above the first position.

According to an example, the calculation unit calculates the measurement magnetic field at the first position near the surface of the object to be measured based on a following formula:

$${H}_{tip} = ( {H}_{1} - {H}_{2} ) * L / Δ Z ,$$

where Hₜᵢₚ is the measurement magnetic field at the first position near the surface of the object to be measured; H₁ is the first magnetic field; H₂ is the second magnetic field; L is an effective length of the giant magneto-impedance probe; and ΔZ is a distance between the second position and the first position.

According to an example, the distance between the second position and the first position is in a range of 1 μm to 2 mm, preferably in a range of 10 μm to 1 mm. The effective length of the giant magneto-impedance probe is in a range of 1 mm to 3 cm, preferably in a range of 3 mm to 2 cm.

According to an example, the positioning unit is further configured to move the giant magneto-impedance probe along the surface of the object to be measured, so as to measure magnetic fields at multiple positions.

According to an example, the magnetic field detection device may further comprise a control unit for controlling one or more of the AC signal source, the measurement circuit, the calculation unit, and the positioning unit, to automatically measure the magnetic fields at multiple positions on the surface of the object to be measured.

According to an embodiment, the present disclosure provides a magnetic field detection device, which may include: a vibrating head on which a giant magneto-impedance GMI probe is mounted; an alternating current AC signal source configured to apply an AC current having a first frequency to the GMI probe; a vibration controller configured to control the vibrating head to vibrate at a second frequency based on a reference signal having the second frequency; a measurement circuit configured to measure an AC voltage signal of the first frequency provided by the GMI probe when the AC current of the first frequency is applied to the GMI probe, and generate a measurement signal indicating the amplitude of the AC voltage signal; an interlock circuit configured to extract the amplitude of the measurement signal based on the reference signal of the second frequency and provide the reference signal to the vibration controller; and a calculation unit configured to determine the magnitude of the magnetic field measured by the GMI probe based on the amplitude of the measurement signal.

In an example, a distance measuring probe is further mounted on the vibrating head, and the vibration controller receives a distance measuring signal provided by the distance measuring probe and adjusts the vibration frequency and amplitude of the vibrating head based on the distance measuring signal.

In an example, the vibrating head includes a piezoelectric material that has no magnetic remanence itself and deforms in response to a voltage applied thereto to generate vibration, during which no magnetic field is generated, thereby not affecting the measurement accuracy of the magnetic field detection device.

In an example, the AC signal source includes: a clock circuit configured to generate a clock signal having the first frequency; and a driving circuit configured to generate an AC current having the first frequency based on the clock signal and provide the AC current to the GMI probe, wherein the clock signal of the first frequency is further provided to the measurement circuit.

In an example, the vibration controller includes: a lock-in amplifier configured to extract the amplitude and phase of the distance measuring signal provided by the distance measuring probe based on the reference signal of the second frequency received from the interlock circuit; and a driving circuit configured to control the amplitude and frequency of a driving voltage signal provided to the vibrating head based on the amplitude and phase of the distance measuring signal, thereby enabling the vibrating head to vibrate at a desired amplitude and frequency.

In an example, the measurement circuit includes: a capacitor, configured to filter out a DC component in the AC voltage signal, one plate of which is connected to a measurement terminal of the GMI probe providing the AC voltage signal; a phase adjustment circuit, an input terminal of which is connected to the other plate of the capacitor, configured to adjust the phase of the AC voltage signal filtered by the capacitor so that the filtered AC voltage signal and the clock signal from the clock circuit have the same phase; a lock-in amplifier connected to an output terminal of the phase adjustment circuit, and configured to extract the amplitude of the AC voltage signal based on the clock signal and output a measurement signal indicating the amplitude of the AC voltage signal; and a voltage-to-current conversion circuit configured to generate a current signal based on the voltage of the measurement signal and provide the current signal to the measurement terminal of the GMI probe to at least partially offset the magnetic field detected by the GMI probe, thereby serving to bias the GMI probe at a more sensitive operating point.

In an example, the interlock circuit includes a lock-in amplifier that generates a reference signal having the second frequency and extracts the amplitude of the measurement signal provided by the measurement circuit based on the reference signal.

In an example, the GMI probe includes a first GMI probe and a second GMI probe, which is located at a higher height than the first GMI probe; and the measurement circuit comprises a first measurement circuit configured to measure a first AC voltage signal provided by the first GMI probe and generate a first measurement signal indicating an amplitude of the first AC voltage signal; and a second measurement circuit configured to measure a second AC voltage signal provided by the second GMI probe and generate a second measurement signal indicating an amplitude of the second AC voltage signal; wherein the magnetic field detection device further comprises a differential amplifier configured to generate a measurement signal indicating a difference between the first measurement signal and the second measurement signal.

In an example, a distance measuring probe is further mounted on the vibrating head, and the vibration controller receives a distance measuring signal provided by the distance measuring probe and adjusts the vibration frequency and amplitude of the vibrating head based on the distance measuring signal.

In an example, the AC signal source includes: a clock circuit configured to generate a clock signal having the first frequency; and a driving circuit configured to generate an AC current having the first frequency based on the clock signal and provide the AC current to the first GMI probe and the second GMI probe, wherein the clock signal of the first frequency is further provided to the first measurement circuit and the second measurement circuit.

In an example, the first measurement circuit includes: a first capacitor, configured to filter out a DC component in the first AC voltage signal, one plate of which is connected to a measurement terminal of the first GMI probe providing the first AC voltage signal; a first phase adjustment circuit, an input terminal of which is connected to the other plate of the first capacitor, configured to adjust the phase of the first AC voltage signal filtered by the first capacitor so that the filtered first AC voltage signal and the clock signal from the clock circuit have the same phase; a first lock-in amplifier connected to an output terminal of the first phase adjustment circuit, and configured to extract the amplitude of the first AC voltage signal based on the clock signal and output a first measurement signal indicating the amplitude of the first AC voltage signal; and a first voltage-to-current conversion circuit configured to generate a first current signal based on the voltage of the first measurement signal and provide the first current signal to the measurement terminal of the first GMI probe to at least partially offset the magnetic field detected by the first GMI probe, thereby serving to bias the first GMI probe at a more sensitive operating point; and
the second measurement circuit includes: a second capacitor, configured to filter out a DC component in the second AC voltage signal, one plate of which is connected to a measurement terminal of the second GMI probe providing the second AC voltage signal; a second phase adjustment circuit, an input terminal of which is connected to the other plate of the second capacitor, configured to adjust the phase of the second AC voltage signal filtered by the second capacitor so that the filtered second AC voltage signal and the clock signal from the clock circuit have the same phase; a second lock-in amplifier connected to an output terminal of the second phase adjustment circuit, configured to extract the amplitude of the second AC voltage signal based on the clock signal and output a second measurement signal indicating the amplitude of the second AC voltage signal; and a second voltage-to-current conversion circuit configured to generate a second current signal based on the voltage of the second measurement signal and provide the second current signal to the measurement terminal of the second GMI probe to at least partially offset the magnetic field detected by the second GMI probe, thereby serving to bias the second GMI probe at a more sensitive operating point.

In an example, the interlock circuit includes a lock-in amplifier that generates a reference signal having the second frequency and extracts the amplitude of the measurement signal provided by the differential amplifier based on the reference signal.

In an example, the differential amplifier is a proportion-adjustable differential amplifier that is calibrated such that, in the absence of a magnetic field, the measurement signal output thereby indicates a zero difference between the first measurement signal and the second measurement signal.

According to an embodiment, the present disclosure provides a magnetic field measurement method, which may comprise: positioning a giant magneto-impedance probe at a first position near a surface of an object to be measured; applying an AC current to the giant magneto-impedance probe and measuring a first AC voltage of the giant magneto-impedance probe; calculating impedance of the giant magneto-impedance probe based on the AC current and the first AC voltage, and determining a first magnetic field based on the impedance; positioning the giant magneto-impedance probe at a second position above the first position; applying the AC current to the giant magneto-impedance probe and measuring a second AC voltage of the probe; calculating impedance of the giant magneto-impedance probe based on the AC current and the second AC voltage, and determining a second magnetic field based on the impedance; calculating a measurement magnetic field at the first position near the surface of the object to be measured based on the first magnetic field and the second magnetic field.

According to an example, the giant magneto-impedance probe is positioned perpendicular to the surface of the object to be measured, and the second position is located vertically above the first position.

According to an example, the measurement magnetic field at the first position near the surface of the object to be measured is calculated based on a following formula:

$${H}_{tip} = ( {H}_{1} - {H}_{2} ) * L / Δ Z ,$$

where Hₜᵢₚ is the measurement magnetic field at the first position near the surface of the object to be measured; H₁ is the first magnetic field; H₂ is the second magnetic field; L is an effective length of the giant magneto-impedance probe; and ΔZ is a distance between the second position and the first position.

According to an example, the method may further comprise: moving the giant magneto-impedance probe along the surface of the object to be measured, to measure magnetic fields at multiple positions.

The above and other features and advantages of the present disclosure will become apparent from the following description of exemplary embodiments in conjunction with the accompanying drawings.

### BRIEF DESCRIPTION OF THE DRAWINGS

FIG. 1 is a schematic circuit diagram for measuring magnetic fields based on the giant magneto-impedance effect in the prior art.

FIG. 2 is a schematic diagram of another GMI probe.

FIG. 3 is a schematic diagram of another GMI probe.

FIG. 4 is a functional block diagram of a magnetic field detection device for detecting weak magnetic fields proximate to a surface of an object based on the GMI effect according to an embodiment of the present disclosure.

FIG. 5 is a schematic diagram of the principle of detecting weak magnetic fields proximate to a surface of an object based on the GMI effect according to an embodiment of the present disclosure.

FIG. 6 is a schematic diagram of a magnetic field detection device for detecting weak magnetic fields on the surface of an object based on the GMI effect according to an embodiment of the present invention.

FIG. 7 is a circuit diagram of the magnetic field detection device shown in FIG. 6.

FIG. 8 is a schematic diagram of a magnetic field detection device for detecting weak magnetic fields on the surface of an object based on the GMI effect according to another embodiment of the present invention.

FIG. 9 is a graph of the magnetic field intensity proximate to a surface of a sample measured using the magnetic field detection device of the present disclosure.

### DETAILED DESCRIPTION

Exemplary embodiments of the present disclosure will be described below with reference to the accompanying drawings. Note that the accompanying drawings may not be drawn to scale.

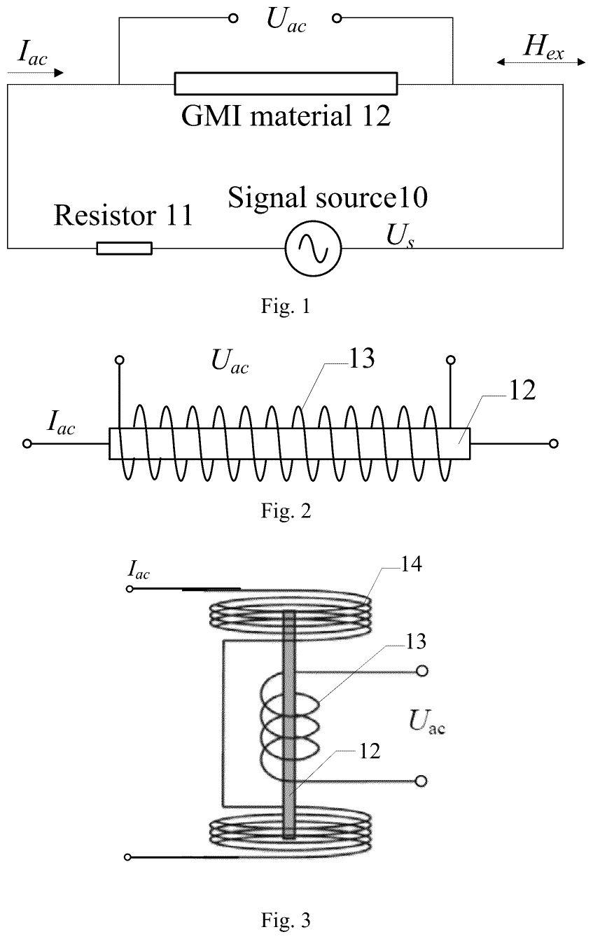

FIG. 1 is a circuit diagram for measuring magnetic fields based on the giant magneto-impedance (GMI) effect in the prior art. The GMI effect refers to a phenomenon that when a high-frequency current passes through a soft magnetic material, the inductive part (or imaginary part) and the resistance part (or real part) of an alternating current (AC) impedance of the material change with an external magnetic field, which is very sensitive, even 1-2 orders of magnitude higher than the giant magnetoresistance (GMR) effect, and can generally reach 10%-120%/Oe, and hence it is called the giant magneto-impedance effect. By using this principle, the relationship between the AC impedance of the material and the magnetic field can be calibrated in advance, and then the AC impedance of the material can be measured, thereby detecting the external magnetic field. As shown in FIG. 1, the AC signal source 10 can apply a current flowing through a GMI material 12, and the resistor 11 can be connected in series with the GMI material 12, to detect the current flowing through the GMI material 12. Here, Us represents a voltage of the signal source 10; I_{ac} represents the AC current flowing through the GMI material 12; U_{ac} represents an AC voltage detected at both ends of the GMI material 12; and Hₑₓ represents an external magnetic field. By using the AC current I_{ac} flowing through the GMI material 12 and the AC voltage U_{ac} at both ends of the GMI material 12, an AC impedance Z=U_{ac}/I_{ac} of the GMI material 12 can be calculated, and then a corresponding magnitude of the external magnetic field Hₑₓ can be determined. In other embodiments, the relationship between the giant magneto-impedance GMI of the material and the external magnetic field Hₑₓ can also be calibrated in advance, and then the AC impedance of the material can be measured, and a GMI value can be calculated to determine the magnitude of the external magnetic field Hₑₓ based on the GMI value. The above two methods are equivalent. For the convenience of description, the above processes are described in this application as determining the external magnetic field based on the AC impedance. The GMI value can be determined based on the following Formula 1 or Formula 2:

$$GMI = Δ Z / Z = ( Z ( {H}_{e x} ) - Z ( {H}_{max} ) ) / Z ( {H}_{max} ) \qquad Formula 1$$

$$GMI = Δ Z / Z = ( Z ( {H}_{e x} ) - Z ( {H}_{0} ) ) / Z ( {H}_{0} ) \qquad Formula 2$$

where Z (Hₑₓ), Z (H₀), and Z (Hₘₐₓ) respectively represent the AC impedance of the material when the external magnetic field is at any value, zero, and saturation state.

The GMI material 12 shown in FIG. 1 can also be referred to as a GMI probe, which generally comprises soft magnetic alloy materials such as Co-based alloys (such as CoSiB, CoFeSiB, etc.) and Fe-based alloys (such as NiFe, FeSiBNbCu, etc.). The GMI material 12 can be formed into amorphous filaments or glass wrapped amorphous filaments. In some embodiments, the GMI material 12 can be formed not only as a single-layer film structure of alloy material, but also as a sandwich structure or multi-layer film structure. The sandwich structure comprises two soft magnetic film layers and a high conductivity metal layer sandwiched between them, and the high conductivity metal may comprise Cu, Ag, Au, etc. Examples of multilayer film structures may comprise alternating stacking structures of soft magnetic films and conductive metal films, or insulating layers such as SiO₂ may also be inserted therebetween. It can be understood that various materials with the GMI effect have been extensively and deeply studied, and the present disclosure is not limited to any specific GMI material and structure.

In the example shown in FIG. 1, the GMI probe may only comprise the GMI material 12 (such as a soft magnetic alloy material), the AC current I_{ac} can be applied to the GMI material 12, and the AC voltage U_{ac} at both ends of the GMI material 12 can be measured, thereby measuring the external magnetic field Hₑₓ. In another embodiment of the GMI probe, as shown in FIG. 2, the GMI probe may comprise a core 12 formed of a GMI material (such as a soft magnetic alloy material), and a solenoid coil 13 surrounding the core 12. The AC current I_{ac} can be applied to the core 12, and the AC voltage U_{ac} output from both ends of the solenoid coil 13 can be measured to measure the external magnetic field Hₑₓ. FIG. 3 shows another embodiment of the GMI probe, which comprises a Helmholtz coil 14 to which the AC current I_{ac} can be applied, with the core 12 placed in a uniform magnetic field generated by the Helmholtz coil 14, the solenoid coil 13 surrounding the core 12, and the AC voltage U_{ac} output at both ends of the solenoid coil 13 being measured. In another embodiment (not shown here), the solenoid coil 13 in the probe shown in FIG. 3 can be omitted, and the AC voltage U_{ac} at both ends of the core 12 can be directly measured. It can be understood that any GMI probe structure described here can be applied in the embodiments of the present disclosure.

The principle of measuring an external magnetic field Hₑₓ based on the GMI effect was discussed above. It can be understood that the GMI probe measures an average magnetic field along an extension direction of the probe within its effective length range. Here, the effective length of the probe refers to a length of the probe that provides the AC voltage U_{ac}. For example, in FIG. 1, when measuring the AC voltage U_{ac} at both ends of the core 12, the effective length of the probe refers to an extension length of the core 12; while in the examples shown in FIGS. 2 and 3, the measured AC voltage U_{ac} is at both ends of the solenoid coil 13 surrounding the core 12, and thus the effective length of the probe refers to the extension length of the solenoid coil 13. This GMI probe structure is not suitable for directly measuring a weak magnetic field proximate to a surface of an object. The weak magnetic field proximate to the surface of the object is generally perpendicular to the surface and will rapidly decay after leaving the surface; that is, it is distributed in a very thin area close to the surface, while the effective length of the GMI probe may be much greater than the attenuation distance of the weak magnetic field on the surface of the object (such as a distance from the surface of the object to a place where the magnetic field decays to a certain percentage), thereby making it difficult to accurately measure the weak magnetic field in micro areas of the surface of the object.

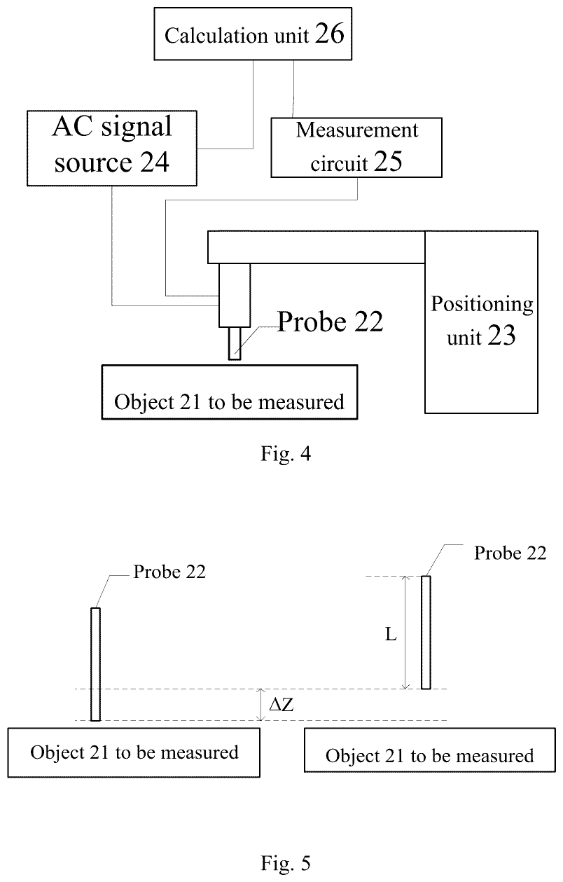

The present disclosure proposes a novel measurement method that can use conventional GMI probes to measure weak magnetic fields on the surfaces of an object. FIG. 4 shows a magnetic field detection device according to an embodiment of the present disclosure, comprising a GMI probe 22, a positioning unit 23, an AC signal source 24, a measurement circuit 25, and a calculation unit 26.

The GMI probe 22 can be any one of the GMI probes described above, supported by the positioning unit 23, and the positioning unit 23 can position the GMI probe 22 to the desired measurement position, such as near the surface of the object 21 to be measured. The positioning unit 23 may comprise a servo motor and an appropriate transmission mechanism to move and position the GMI probe 22 in a three-dimensional space, or at least in a linear direction along the surface of the object and in a vertical direction perpendicular to the surface of the object.

The AC signal source 24 can provide the AC current I_{ac} to the GMI probe 22, and the measurement circuit 25 can measure the AC voltage U_{ac} on the GMI probe 22. In one embodiment, the AC signal source 24 can also be connected to the measurement circuit 25 to provide information related to the applied AC current I_{ac}, such as clock signals, to the measurement circuit 25, so that the measurement circuit 25 can accurately measure the voltage signal on the GMI probe 22. For example, the measurement circuit 25 can use the clock signals to filter the AC voltage signal detected on the GMI probe 22 to eliminate noise and accurately extract the AC voltage U_{ac}. The calculation unit 26 can be connected to the AC signal source 24 and the measurement circuit 25 to receive the AC current I_{ac} and the AC voltage U_{ac}, and use the AC current I_{ac} and the AC voltage U_{ac} to calculate the impedance of the GMI probe 22 Z=U_{ac}/I_{ac}, thereby further determining the magnitude of the external magnetic field based on the impedance Z. In another embodiment, the calculation unit 26 can also calculate the GMI value based on the measured impedance value Z, for example, using Formula 1 or Formula 2 above to calculate the GMI value, and then determine the corresponding magnitude of the external magnetic field based on the GMI value. In another embodiment, the AC signal source 24 can be set to provide a predetermined AC current I_{ac}, which is equivalent to that the AC current I_{ac} is known and fixed, and then the calculation unit 26 can also directly determine the magnitude of the external magnetic field based on the measured AC voltage U_{ac}. It should be understood that the three methods, i.e. determining the magnitude of the external magnetic field based on the impedance Z, determining the magnitude of the external magnetic field based on the GMI value, or determining the magnitude of the external magnetic field based on the AC voltage U_{ac} when the AC current I_{ac} is fixed, are equivalent. All three methods are essentially based on the relationship of AC impedance changing with the external magnetic field, and thus the magnitude of the external magnetic field is determined according to the measured AC impedance value. For the sake of convenience and simplicity, the following description will be based on the impedance Z to determine the magnitude of the external magnetic field, but it should be understood that this description encompasses the above three and any other equivalent ways.

The measurement process and principle of the magnetic field detection device of the present disclosure will be described below with reference to FIG. 5. As shown in the left figure of FIG. 5, the positioning unit 23 is firstly used to position the GMI probe 22 near the surface of the object to be measured, which is referred to as the first position. It can be understood that when in the first position, the GMI probe 22 can directly contact the surface of the object 21 to be measured, or the two can be separated by a small distance. The lower end of the GMI probe 22 is basically located in a distribution area of the magnetic field to be measured. The positioning unit 23 can make the GMI probe 22 substantially perpendicular to the surface of the object 21 to be measured. In this state, the AC signal source 24 provides the AC current I_{ac} to the GMI probe 22; the measurement circuit 25 can measure the first AC voltage U_{ac1} on the GMI probe 22; and the calculation unit 26 can calculate the first impedance Z₁=U_{ac1}/I_{ac} of the GMI probe 22 based on the AC current I_{ac} and the first AC voltage U_{ac1}, and further determine the magnitude of the first external magnetic field H₁ based on the first impedance Z₁. As mentioned earlier, the first magnetic field H₁ is an average magnetic field of the area where the GMI probe 22 is located (i.e., the area where the effective length L of the GMI probe 22 extends) when the GMI probe 22 is in the first position.

Then, as shown in the right figure of FIG. 5, the positioning unit 23 is used to move the GMI probe 22 substantially vertically upward by a distance of ΔZ, so that the GMI probe 22 moves from the first position to the second position located above it. In the second position, similarly, the AC signal source 24 provides the AC current I_{ac} to the GMI probe 22; the measurement circuit 25 can measure the second AC voltage U_{ac2} on the GMI probe 22; and the calculation unit 26 can calculate the second impedance Z₂=U_{ac2}/I_{ac} of the GMI probe 22 based on the AC current I_{ac} and the second AC voltage U_{ac2}, and further determine the magnitude of the second external magnetic field H₂ based on the second impedance Z₂. As mentioned earlier, the second magnetic field H₂ is an average magnetic field of the area where the GMI probe 22 is located (i.e., the area where the effective length L of the GMI probe 22 extends) when the GMI probe 22 is in the second position.

The inventor researches and finds that if the space occupied by the effective length L of the GMI probe 22 is divided into N parts in a unit of ΔZ, i.e., N=L ΔZ, in the case shown in the left figure of FIG. 5, the space occupied by the GMI probe 22 can be represented as P1, P2, . . . , PN from bottom to top. When the GMI probe 22 moves up by ΔZ, as shown in the right figure of FIG. 5, the space occupied by the GMI probe 22 from bottom to top can be represented as P2, P3, . . . , PN, PN+1. Therefore, the first magnetic field H₁ and the second magnetic field H₂ measured above can be represented by the following Formulas 3 and 4, respectively:

$${H}_{1} = ( {H}_{P 1} + {H}_{P 2} + … + {H}_{P N} ) / N \qquad Formula 3$$

$${H}_{2} = ( {H}_{P 2} + {H}_{P 3} + … + {H}_{P N + 1} ) / N \qquad Formula 4$$

where H_{P1}, is the magnetic field in the i-th space divided as above. Then, by subtracting Formula 4 from Formula 3, a following Formula 5 can be obtained:

$${H}_{1} - {H}_{2} = ( {H}_{P 1} - {H}_{P N + 1} ) / N \qquad Formula 5$$

The inventor further analyzes the characteristics of weak magnetic fields on the surface of the object, which are generally distributed in very thin and small areas on the surface of the object, such as in space P1 and adjacent areas. Therefore, H_{P1} can be regarded as the magnetic field strength on the surface of the object. Compared to the magnetic field distribution area, the length L of the GMI probe 22 is significantly larger. However, due to the rapid decay of the magnetic field proximate to the surface of the object with a distance from the surface increasing, it can be considered that the upper end of the length L of the GMI probe 22 extends beyond the weak magnetic field distribution area. Therefore, H_{PN}+1 can be considered as almost zero, which means it does not contain the surface magnetic field component to be measured. Furthermore, based on this analysis, Formula 6 can be obtained from Formula 5:

$${H}_{tip} = ( {H}_{1} - {H}_{2} ) * N = ( {H}_{1} - {H}_{2} ) * L / Δ Z \qquad Formula 6$$

Therefore, the calculation unit 26 can use the first magnetic field H₁ and the second magnetic field H₂ measured at the first and second positions respectively, based on Formula 6, to calculate the magnetic field measurement value Hₜᵢₚ at the surface position of the object 21 to be measured; that is, the magnetic field Hₜᵢₚ at the lower end position of the GMI probe 22 when it is located at the first position.

In the above measurement process of the present disclosure, in order to accurately and finely measure the magnetic field in small areas on the surface of the object, the vertical movement distance ΔZ should not be too large. Generally, it can be in a range of 1 μm to 2 mm, preferably in the range of 10 μm to 1 mm. If the moving distance ΔZ is too large, the measured value may be inaccurate due to the fact that what is measured is an average magnetic field within a range of the probe's lower end moving distance ΔZ, and thus it cannot reflect the actual magnetic field distribution and transformation within the range of the distance ΔZ. On the other hand, if the moving distance ΔZ is too small, such as less than 1 m, the differential signal between the two measurements may be too small to accurately measure the magnetic field changes between the first and second positions. In addition, as mentioned above, the GMI probe 22 should have an effective length L of an appropriate size, so that it can extend to near or even beyond the boundary of the magnetic field distribution area on the surface of the object, i.e., the magnetic field distribution near the upper end of the GMI probe 22 is essentially zero. In some embodiments of the present disclosure, the effective length L of the GMI probe 22 may be in a range of 1 mm to 3 cm, preferably in a range of 3 mm to 2 cm. A length L that is too long is not conducive to the sensitivity of the above measurement process. If the sensitivity of the GMI probe 22 itself is S, measured in V/nT (volts per nanotesla), then the sensitivity S′ of the process of measuring the magnetic field through the differential method can be expressed as S′=S*AZ/L.

The above describes the process and method of measuring weak magnetic fields on the surface of an object using the magnetic field detection device of the present disclosure. It should be understood that although in the above description, the GMI probe 22 is positioned at the first position to measure the first magnetic field H₁, and then is positioned at the second position above the first position to measure the second magnetic field H₂, it is also possible to first position it at the second position to measure the second magnetic field H₂, and then position it at the first position to measure the first magnetic field H₁.

In some embodiments, the positioning unit 23 can not only move the GMI probe 22 in a vertical direction, but also move the GMI probe 22 in a plane, so as to measure the magnetic field distribution on the surface of the object 21 to be measured. In some embodiments, the positioning unit 23 may move the GMI probe 22 multiple times in the vertical direction, such as to a third position above the second position, a fourth position above the third position, and so on. In this way, magnetic measurements taken at the second and third positions can be used to determine the magnitude of the magnetic field at the second position, magnetic measurements taken at the third and fourth positions can be used to determine the magnitude of the magnetic field at the third position, and so on. Therefore, the three-dimensional magnetic field intensity distribution above the surface of the object 21 to be measured can be obtained.

The magnetic field detection device of the present disclosure determines the magnetic field in a thin area of the surface of the object by measuring the magnetic fields at two height positions on the surface of the object, and then calculating a difference between the two. This not only takes advantage of the high sensitivity and low cost of the GMI sensors, but also eliminates system noise and environmental noise through differential measurement, thereby enabling more accurate measurement of weak magnetic fields on the surface of the object. In one embodiment, the magnetic field detection device may further comprise a magnetic shielding cover, and the sample 21 to be measured and the GMI probe 22 may be placed inside the magnetic shielding cover, which can shield the geomagnetic field and further improve the accuracy of the measurement.

FIG. 6 is a schematic diagram of a magnetic field detection device according to an embodiment of the present disclosure, which is further improved on the basis of the magnetic field detection device shown in FIG. 4 to meet the requirements of high-speed and high-precision measurement.

Referring to FIG. 6, the magnetic field detection device may include a vibrating head 110 on which a GMI probe 112 and a distance measuring probe 114 are mounted. The vibrating head 110 is preferably a vibration device that does not involve a magnetic field, such as a device that realizes vibration by driving an electromagnetic coil, because the magnetic field generated by the electromagnetic coil may affect the measurement accuracy of the magnetic field detection device. In some embodiments, the vibrating head 110 may be a piezoelectric vibrating head including a piezoelectric material that deforms in response to an applied voltage to drive the GMI probe 112 and the distance measuring probe 114 mounted thereon to vibrate back and forth in a direction toward and away from a sample to be measured (not shown). In addition to not generating any magnetic field, the advantages of using a piezoelectric vibrating head include easy control of the direction, amplitude, and frequency of vibration. Specifically, the direction of vibration can be determined by setting the orientation of the piezoelectric material, the amplitude of vibration can be determined by setting the amplitude of the voltage applied to the piezoelectric material, and the frequency of vibration depends on the change frequency of the voltage value of the driving signal. Vibration can be easily achieved by applying an AC voltage signal of a predetermined frequency to the piezoelectric material.

The GMI probe 112 may be any of the aforementioned GMR probes, and will not be described repeatedly here. The distance measuring probe 114 may be a laser distance measuring probe, such as a Time-of-Flight (ToF) sensor, and the amplitude of the sensing signal generated thereby may indicate the distance from the probe to the sample to be measured. It can be understood that when the vibrating head 110 drives the GMI probe 112 and the distance measuring probe 114 mounted thereon to vibrate back and forth in the direction toward and away from the sample to be measured, the sensing signal output by the distance measuring probe 114 may also oscillate at the same frequency.

With continued reference to FIG. 6, the magnetic field detection device may further include an AC signal source 120 and a measurement circuit 140. The AC signal source 120 may apply an AC current to the GMI probe 112 for magnetic field measurement; the measurement circuit 140 may measure the AC voltage on the GMI probe 112, and then calculate the impedance of the GMI probe 112 to determine the magnitude of the magnetic field to be measured. In some embodiments, as will be described in detail below, the AC signal source 120 may generate an AC signal of a predetermined frequency based on a clock signal S_{clk} and apply the signal to the GMI probe 112 for magnetic field measurement, which is referred to as a measurement frequency or a first frequency in this application. As shown in FIG. 6, the AC signal source 120 further provides a clock signal S_{clk} indicating the measurement frequency to the measurement circuit 140, enabling the measurement circuit 140 to accurately demodulate the sensing signal of the first frequency from the sensing signal provided by the GMI probe 112, extract amplitude information of the sensing signal, and output a measurement signal indicating the amplitude information. The measurement circuit 140 may provide the measurement signal to the interlock circuit 150, and further determine the magnitude of the magnetic field to be measured, which will be discussed in further detail below.

The magnetic field detection device may further include a vibration controller 130 that provides a driving signal to drive the vibrating head 110 to vibrate. As shown in FIG. 6, the vibration controller 130 may receive a reference signal Sᵣer from the interlock circuit 150, where the reference signal S_{ref} may indicate a vibration frequency, also referred to as a second frequency in this application, so that the vibration controller 130 may generate a driving signal having the vibration frequency based on the reference signal S_{ref}, thereby causing the vibrating head 110 to vibrate back and forth at the vibration frequency. In some embodiments, the vibration controller 130 may further receive a distance measuring signal from the distance measuring probe 114 as feedback, thereby implementing closed-loop control of the vibration frequency and amplitude of the vibrating head 110, which will be described in further detail below.

The interlock circuit 150 may generate an internal reference signal S_{ref} having a first frequency and provide the reference signal S_{ref} to the vibration controller 130 for controlling the vibration frequency of the vibrating head 110; that is, the vibration frequency is equal to the first frequency of the reference signal S_{ref} It can be understood that when the vibrating head 110 vibrates, since the micro-area magnetic field on the surface of the object to be measured decreases rapidly as the distance from the object to be measured increases, the amplitude of the sensing signal generated by the GMI probe 112 also changes with the vibration of the vibrating head 110, so that the measurement signal provided by the measurement circuit 140 to the interlock circuit 150 also oscillates at the first frequency. The interlock circuit 150 not only provides the reference signal S_{ref} to the vibration controller 130, but also uses the reference signal S_{ref} to extract amplitude information of the measurement signal provided by the measurement circuit 140, where the amplitude information corresponds to the difference in the magnitude of the magnetic field measured at two positions when the GMI probe 112 vibrates between the two positions, that is, the value of the magnetic field Hₜᵢₚ, at the lower end position of the GMI probe 112 indicated by Formula 6 above, thereby enabling accurate measurement of the external magnetic field. The interlock circuit 150 may provide the extracted amplitude information to the calculation unit 160, and the calculation unit 160 may determine the magnitude of the external magnetic field based on the amplitude information.

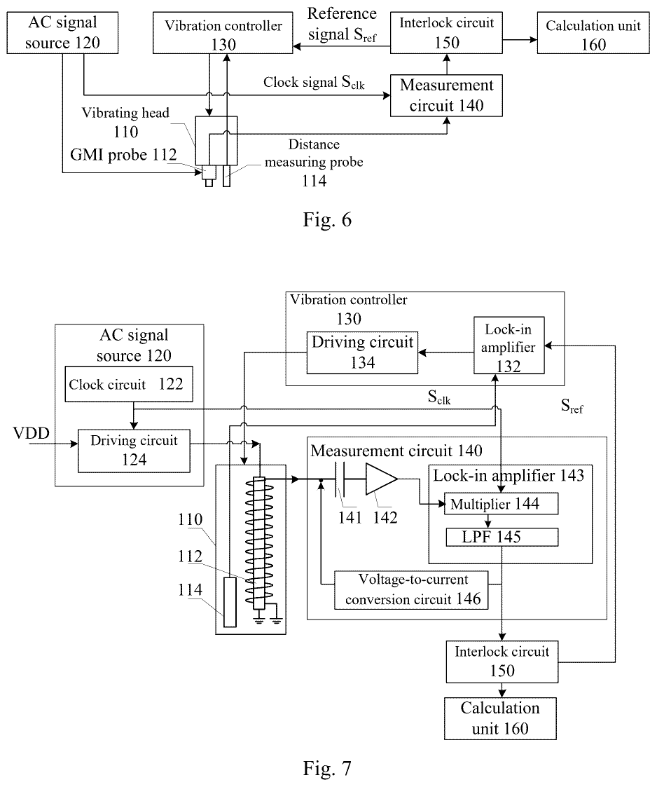

FIG. 7 is a circuit diagram of the magnetic field detection device shown in FIG. 6, and the specific operation of the magnetic field detection device will be described below with reference to this circuit diagram. As shown in FIG. 7, the GMI probe 112 and the distance measuring probe 114 may be mounted on the vibrating head 110. FIG. 7 shows an exemplary structure of the GMI probe 112, but the GMI probe 112 may also adopt any other exemplary structure described above or developed in the future. The AC signal source 120 for providing an AC current for magnetic field measurement to the GMI probe 112 may include a clock circuit 122 and a driving circuit 124. The clock circuit 122 may generate a clock signal S_{clk} of a predetermined frequency, and the driving circuit 124 may receive a DC voltage signal VDD and generate an AC current signal of the same frequency based on the clock signal Sek for application to the GMI probe 112. The frequency of the clock signal S_{clk}, i.e., the frequency of the AC current signal applied to the GMI probe 112, may be referred to as the measurement frequency or the first frequency, which may be, for example, in a range of 10 kHz to 100 MHz, preferably in a range of 100 kHz to 10 MHz. As an example, the frequency of the clock signal S_{clk} may be, for example, 2 MHz. The driving circuit 124 may generate an AC current signal having this frequency and a predetermined amplitude and provide it to the GMI probe 112. The clock circuit 122 may also provide the clock signal S_{clk} to the measurement circuit 140.

The vibration controller 130 may include a lock-in amplifier 132 and a driving circuit 134. The lock-in amplifier 132 may receive a reference signal S_{ref} provided by the interlock circuit 150 and a distance measuring signal provided by the distance measuring probe 114. The amplitude of the distance measuring signal may indicate the distance between the distance measuring probe 114 and the object to be measured, and the frequency of the distance measuring signal may indicate the vibration frequency of the distance measuring probe 114, i.e., the vibration frequency of the vibrating head 110. The lock-in amplifier 132 may use the reference signal S_{ref} as a reference to extract the amplitude and phase of the distance measuring signal fed back by the distance measuring probe 114, and provide the amplitude and phase information to the driving circuit 134. The driving circuit 134 may control the amplitude and phase of the driving voltage signal provided to the vibrating head 110 based on the amplitude and phase information, thereby causing the vibrating head to vibrate at a desired amplitude, phase, and frequency. For example, when there is a phase difference between the fed-back distance measuring signal and the reference signal S_{ref} the driving circuit 134 may adjust the phase of the driving voltage signal for the vibrating head 110 to minimize the phase difference between the fed-back distance measuring signal and the reference signal S_{ref} In addition, the driving circuit 134 may adjust the amplitude of the driving voltage signal for the vibrating head 110 so that the amplitude of the distance measuring signal fed back by the distance measuring probe 114 reaches a desired value, i.e., the vibrating head 110 can vibrate at a desired distance above the object to be measured.

It will be appreciated that in some embodiments, the distance measuring probe 114 and the lock-in amplifier 132 may also be omitted, and the driving circuit 134 may directly generate a driving voltage signal having a second frequency and a predetermined amplitude based on the reference signal S_{ref} provided by the interlock circuit 150 to drive the vibrating head 110 to vibrate. The driving circuit 134 may also adjust the amplitude of the driving voltage signal according to, for example, user settings, so that the vibrating head 110 vibrates with a corresponding amplitude. However, when the vibrating head 110 operates for a long time, its vibration state may drift due to accumulated charges, deviating from the initial vibration position. In this case, it may be necessary to use the driving circuit 134 to perform a reset operation on the vibrating head 110 to restore it to the initial state. Compared with this embodiment, the use of the distance measuring probe 114 can monitor the vibration state of the vibrating head 110 in real time, ensuring that the vibrating head 110 vibrates at the desired frequency and amplitude, thereby ensuring measurement accuracy, and is therefore preferred.

The measurement circuit 140 may be used to measure the AC voltage signal generated on the GMI probe 112, which is also referred to as a sensing signal, when the driving circuit 124 applies an AC current signal to the GMI probe 112. Specifically, the measurement circuit 140 may include a capacitor 141, one plate of which is connected to a measurement terminal on the GMI probe 112 for providing an AC voltage signal (i.e., the sensing signal), and the other plate of which may be connected to a downstream phase adjustment circuit 142. The capacitor 141 may block the DC component in the AC voltage signal output by the GMI probe 112, allowing only the AC component to pass through the capacitor, and after adjusting its phase by the phase adjustment circuit 142, provide it to the lock-in amplifier 143. The lock-in amplifier 143 receives the clock signal S_{clk} provided by the clock circuit 122, uses the clock signal S_{clk} as a reference signal, extracts amplitude information of the AC voltage signal received from the phase adjustment circuit 142, and outputs a measurement signal indicating the amplitude information. It will be appreciated that the AC voltage signal U_{ac} output by the GMI probe 112 has the same frequency as the AC current signal I_{ac} applied to the GMI probe 112, i.e., equal to the frequency of the clock signal S_{clk}, also referred to as the measurement frequency or the first frequency. Therefore, when the lock-in amplifier 143 uses the clock signal S_{clk} as a reference signal, it can accurately extract amplitude information from the AC voltage signal U_{ac} provided by the phase adjustment circuit 142. The phase adjustment circuit 142 may adjust the phase of the AC voltage signal U_{ac} to be the same as the phase of the clock signal S_{clk}, so that the amplitude extracted by the lock-in amplifier 143 has a maximum value. The phase adjustment amount of the phase adjustment circuit 142 may be calibrated in advance so that the output AC voltage signal U_{ac} has the same phase as the clock signal S_{clk}, thereby maximizing the amplitude of the signal output by the lock-in amplifier 143.

The lock-in amplifier 143 may include a multiplier 144 and a low-pass filter (LPF) 145. Assuming that the AC voltage signal U_{ac} received by the lock-in amplifier 143 from the phase adjustment circuit 142 can be expressed as U_{ac} A₁*sin(ω₁t+p₁), where A₁ represents an amplitude, ω₁ represents an angular frequency, and p₁ represents a phase, and the clock signal S_{clk} can be expressed as S_{clk} A₂*sin(ω₁t+p₁), where A₂ represents an amplitude, both having the same angular frequency ω, and phase p₁ but different amplitudes A₁ and A₂, then the signal output after multiplying the AC voltage signal U_{ac} and the clock signal S_{clk} in the multiplier 144 can be expressed as the following Formula 7:

$${U}_{a c} * {S}_{clk} = ( {A}_{1} * {A}_{2} ) / 2 \{ cos [ ( {ω}_{1} - {ω}_{1} ) t + ( {p}_{1} - {p}_{1} ) ] - cos [ ( {ω}_{1} + {ω}_{1} ) t + ( {p}_{1} + {p}_{1} ) ] \} = ( {A}_{1} * {A}_{2} ) / 2 \{ 1 - cos ( 2 {ω}_{1} t + 2 {p}_{1} ) \} = ( {A}_{1} * {A}_{2} ) / 2 - ( {A}_{1} * {A}_{2} ) / 2 * cos ( 2 {ω}_{1} t + 2 {p}_{1} ) \qquad Formula 7$$

It can be seen that the signal output by the multiplier 144 includes a DC component A₁*A₂/2 and an AC component (A₁*A₂/2)*cos(2ω₁t+2p₁). The low-pass filter 145 can filter out the high-frequency AC component and allow only the low-frequency DC component to pass through, which is output as a measurement signal. It will also be appreciated that when the amplitude value A₂ of the clock signal S_{clk} as the reference signal is a known value, the output measurement signal (i.e., the DC component) can indicate the amplitude of the AC voltage signal U_{ac} provided by the GMI probe 112.

With continued reference to FIG. 7, the measurement circuit 140 may further include a voltage-to-current conversion circuit 146, which may convert the voltage of the measurement signal output by the lock-in amplifier 143 into a current and feed the current back to the measurement terminal of the GMI probe 112, shown in FIG. 7 as the signal output terminal of the coil. When this feedback current flows through the coil, it can generate a magnetic field opposite to the direction of the measured magnetic field, i.e., at least partially offsetting the magnetic field measured by the GMI probe 112, which helps to bias the GMI probe 112 to an optimal operating point, or an operating point with higher sensitivity, thereby improving measurement accuracy. It will be appreciated that GMI probes generally have the highest sensitivity under zero magnetic field, i.e., they can most sensitively measure changes in a magnetic field. Therefore, by introducing a feedback path in the measurement circuit 140 to substantially offset the magnetic field at the GMI probe through current compensation, the GMI probe can be biased to the optimal operating point, thereby improving the measurement accuracy.

The lock-in amplifier 143 may provide its output measurement signal to the interlock circuit 150. It will be appreciated that when the GMI probe 112 is stationary, the magnitude of the external magnetic field it measures also remains unchanged. At this time, the GMI probe 112 has a fixed impedance, so the measurement signal output by the lock-in amplifier 143 can remain unchanged, which means that the DC component A1*A2/2 remains unchanged, i.e., the amplitude A₁ of the AC voltage signal U_{ac} output by the GMI probe 112 remains unchanged. When the GMI probe 112 vibrates back and forth in a vertical direction away from and close to the object to be measured, since the surface magnetic field of the object to be measured decays rapidly with distance from the surface, the amplitude A₁ of the AC voltage signal U_{ac} output by the GMI probe 112 also changes at the vibration frequency, i.e., the second frequency, which manifests as the measurement signal output by the lock-in amplifier 143 oscillating at the second frequency. The interlock circuit 150 may extract amplitude information of the measurement signal output by the lock-in amplifier 143, which corresponds to the difference in the magnitude of the magnetic field measured at two positions when the GMI probe 112 vibrates back and forth between the two positions, i.e., the value of the magnetic field Hₜᵢₚ, at the lower end position of the GMI probe 112 indicated by Formula 6 above, thereby enabling accurate measurement of the external magnetic field. Specifically, the interlock circuit 150 may also be implemented as a lock-in amplifier that generates an internal reference signal S_{ref} having a second frequency, uses the internal reference signal S_{ref} to extract the amplitude value of the measurement signal output by the measurement circuit 140 when oscillating at the second frequency, and also provides the reference signal S_{ref} to the vibration controller 130 for controlling the vibration of the vibrating head 110. To ensure that the measurement circuit 140 can output a measurement signal oscillating at the second frequency through the low-pass filter 145, the second frequency (i.e., the vibration frequency) should be less than the first frequency (i.e., the measurement frequency) of the AC voltage signal U_{ac} output by the GMI probe 112. Preferably, the second frequency is much less than the first frequency; for example, the first frequency is more than ten times the second frequency. As an example, the second frequency may be in a range of 1 Hz to 1000 Hz, preferably in a range of 10 Hz to 1000 Hz. For example, in one example, the first frequency may be 2 MHz and the second frequency may be 87 Hz. When the second frequency is greater than 10 Hz, the voltage noise spectral density of the GMI probe 112 can also be reduced, for example, to a level below 100 μV/\sqrt{Hz}.

As previously described, the interlock circuit 150 provides the extracted amplitude information of the measurement signal provided by the measurement circuit 140 to the calculation unit 160, which may determine the magnitude of the external magnetic field based on the amplitude information, for example, by calculating the magnitude of the external magnetic field Hₜᵢₚ at the lower end of the GMI probe 112 according to Formula 6 above. The calculation unit 160 may be implemented in a host computer such as a computer, which may also receive information about the AC current signal I_{ac} provided to the GMI probe 112, or the user may input this information into the host computer, or the information is preset information in the host computer. The host computer may use the information of the AC current signal I_{ac} and the amplitude information of the measurement signal received from the interlock circuit 150 to calculate the magnitude of the external magnetic field, the principle of which has been described in detail above and will not be repeated here.

Although not shown, the magnetic field measurement device shown in FIGS. 6 and 7 may further include a positioning device for positioning and moving the object to be measured in a plane, which may move the object to be measured in a plane so that the GMI probe 112 can measure the magnetic field at different positions on the surface of the object to be measured. The positioning device may also provide position information of the object to be measured, such as planar two-dimensional coordinates, to the calculation unit 160 such as a host computer, which may associate the measured magnetic field magnitude with the two-dimensional coordinates to obtain a two-dimensional magnetic field distribution map of the surface of the object to be measured.

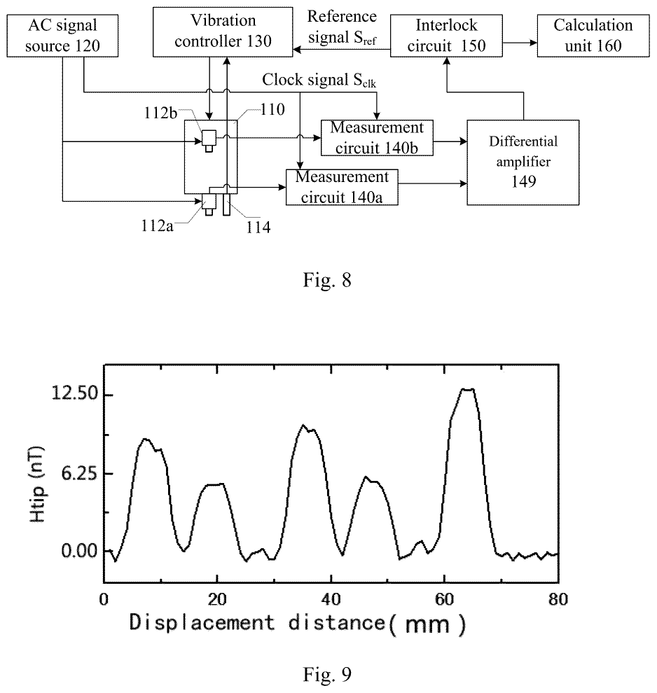

The structure of the magnetic field measurement device shown in FIGS. 6 and 7 and the principle of using it to measure the micro-area magnetic field on the surface of an object have been described above. It should be understood that the object to be measured may be located in a larger external environmental magnetic field such as the geomagnetic field, so the measured magnetic field is actually the superposition of the magnetic field of the object to be measured itself and the external environmental magnetic field such as the geomagnetic field. In order to eliminate the influence of the environmental magnetic field and accurately measure the magnetic field of the object to be measured itself, in some embodiments of the present disclosure, as shown in FIG. 8, two GMI probes may be provided on the vibrating head 110. One GMI probe 112a may measure the superposition of the magnetic field of the object to be measured itself and the environmental magnetic field such as the geomagnetic field, and the other GMI probe 112b may be used to measure the environmental magnetic field. By subtracting the measurement result of the GMI probe 112b from the measurement result of the GMI probe 112a, the magnetic field of the object to be measured itself can be accurately determined, which can further improve the measurement accuracy. This embodiment will be described below with reference to FIG. 8. It should be understood that the same or similar components in this embodiment as those in the embodiment shown in FIGS. 6 and 7 are denoted by the same or similar reference numerals, and since these same or similar components have been described in detail above, repeated descriptions thereof will be omitted here, and the different parts will be focused on.

Referring to FIG. 8, two GMI probes may be vertically arranged on the vibrating head 110. A first GMI probe 112a may be located at a first height, and a second GMI probe 112b may be located at a second height above the first GMI probe 112a, i.e., having a greater height than the first GMI probe 112a, with the planar projections of the first GMI probe 112a and the second GMI probe 112b on the surface of the object to be measured being at the same position. Since the first GMI probe 112a is closer to the surface of the object to be measured, it may be used to measure the magnetic field on the surface of the object to be measured, which is actually the superposition of the surface magnetic field of the object to be measured and the environmental magnetic field (e.g., geomagnetic field). Since the second GMI probe 112b is located at a higher position than the first GMI probe 112a, where the surface magnetic field of the object to be measured is almost zero, the second GMI probe 112b can only measure the environmental magnetic field (e.g., geomagnetic field). Preferably, the first GMI probe 112a and the second GMI probe 112b may be identical to each other, and each may be identical to any of the GMI probes described above, with the same measurement principle as described above, which will not be repeated here.

The AC signal source 120 may provide AC current signals to the first GMI probe 112a and the second GMI probe 112b, and provide a clock signal S_{clk} to the first measurement circuit 140a and the second measurement circuit 140b. The vibration controller 130 may control the vibrating head 110 to vibrate at a second frequency based on a reference signal S_{ref} of the second frequency received from the interlock circuit 150. The first measurement circuit 140a may measure a first AC voltage signal U_{ac1} provided by the first GMI probe 112a based on the clock signal S_{clk}, and generate a first measurement signal indicating the amplitude of the first AC voltage signal U_{ac1}; the second measurement circuit 140b may measure a second AC voltage signal U_{ac2} provided by the second GMI probe 112b based on the clock signal S_{clk}, and generate a second measurement signal indicating the amplitude of the second AC voltage signal U_{ac2}. A differential amplifier 149 may receive the first measurement signal provided by the first measurement circuit 140a and the second measurement signal provided by the second GMI probe 112b as inputs, and generate a measurement signal indicating the difference between the first measurement signal and the second measurement signal. It will be appreciated that this difference indicates the difference between the magnetic field measured by the first GMI probe 112a and that measured by the second GMI probe 112b, thereby indicating the surface magnetic field of the object to be measured after excluding the influence of the environmental magnetic field. The interlock circuit 150 may extract the amplitude of the measurement signal provided by the differential amplifier 149 based on the reference signal S_{ref} of the second frequency, and provide the amplitude to the calculation unit 160. The calculation unit 160 may determine the magnitude of the magnetic field on the surface of the object to be measured based on the amplitude. Each of the first measurement circuit 140a and the second measurement circuit 140b shown in FIG. 8 may be the same as the measurement circuit 140 shown in FIG. 7, and the AC signal source 120, vibration controller 130, interlock circuit 150, and calculation unit 160 shown in FIG. 8 may be the same as those shown in FIG. 7, respectively, and repeated descriptions thereof are omitted here.

Ideally, the first GMI probe 112a and the second GMI probe 112b are completely identical to each other, i.e., their output signals under the same magnetic field are identical, so that the difference between their output signals can accurately reflect the surface magnetic field of the object to be measured after excluding the influence of the environmental magnetic field. However, in practice, it is difficult or almost impossible to make two GMI probes completely identical, i.e., their output signals under the same magnetic field may differ from each other, which affects the measurement accuracy of the magnetic field measurement device shown in FIG. 8. In one embodiment, the differential amplifier 149 may be a proportion-adjustable differential amplifier, i.e., it may adjust the proportion (or weight or gain) of the two input signals received at the two input ports. During the manufacturing phase of the magnetic field measurement device shown in FIG. 8, the proportion of the two input signals received at the two input ports of the proportion-adjustable differential amplifier may be calibrated such that in the absence of an external magnetic field, or when the first GMI probe 112a and the second GMI probe 112b are in the same magnetic field, the signal output by the proportion-adjustable differential amplifier 150 indicates a zero difference between the first measurement signal provided by the first measurement circuit 140a and the second measurement signal provided by the second measurement circuit 140b. That is, by setting different input signal proportions, the difference between the first GMI probe 112a and the second GMI probe 112b is offset, thereby further improving the measurement accuracy of the magnetic field detection device.

Other aspects of the magnetic field detection device shown in FIG. 8 may be the same as the embodiments described above with reference to FIGS. 6 and 7, and repeated descriptions thereof are omitted here.

The magnetic field measurement method of the present disclosure has been described above with reference to FIGS. 4 and 5. For ease of understanding, it is summarized as follows.

According to an embodiment, a magnetic field measurement method may comprise:
Step 1, positioning a giant magneto-impedance probe at a first position near a surface of an object to be measured;
Step 2, applying an AC current to the giant magneto-impedance probe and measuring a first AC voltage of the giant magneto-impedance probe;
Step 3, calculating impedance of the giant magneto-impedance probe based on the AC current and the first AC voltage, and determining a first magnetic field based on the impedance;
Step 4, positioning the giant magneto-impedance probe at a second position above the first position;
Step 5, applying the AC current to the giant magneto-impedance probe and measuring a second AC voltage of the giant magneto-impedance probe;
Step 6, calculating impedance of the giant magneto-impedance probe based on the AC current and the second AC voltage, and determining a second magnetic field based on the impedance; and
Step 7, calculating a measurement magnetic field at the first position near the surface of the object to be measured based on the first magnetic field and the second magnetic field.

Here, in steps 1 and 4, the giant magneto-impedance probe can be positioned substantially perpendicular to the surface of the object to be measured, and the second position can be located vertically above the first position.

In step 7, the measurement magnetic field at the first position near the surface of the object to be measured can be calculated based on Formula 6 above.

In addition, in the magnetic field measurement method of the present disclosure, the giant magneto-impedance probe can also be moved along the surface of the object to be measured to measure the magnetic fields at multiple positions; and it can also move the giant magneto-impedance probe multiple times in the vertical direction to measure the magnetic fields at multiple vertical positions. Ultimately, the magnetic field distribution in the three-dimensional space above the surface of the object to be measured can be obtained.

Some details of the magnetic field measurement method of the present disclosure can refer to the description of FIGS. 4-5 above, which will not be repeated here.

FIG. 9 shows a magnetic field intensity graph obtained by measuring a magnetic ink area on a 20 euro banknote using the magnetic field detection device and method of the present disclosure, in which the horizontal axis represents a displacement distance along a horizontal line on a surface of a sample, and the vertical axis represents a measurement magnetic field intensity. During a measurement process, the first position is approximately 0.2 mm away from the surface of the sample, and the second position is approximately 0.7 mm away from the surface of the sample, with a vertical movement distance ΔZ of approximately 0.5 mm. From the graph of FIG. 9, it can be seen that the magnetic field detection device and method of the present disclosure can accurately detect the five hard magnetic areas on the surface of the sample, successfully achieving weak magnetic detection in the micro areas of the surface of the sample.

In the present disclosure, a magnetic field detection device comprises: a giant magneto-impedance probe; an AC signal source configured to apply an AC current to the giant magneto-impedance probe; a measurement circuit configured to measure an AC voltage on the giant magneto-impedance probe; a calculation unit configured to calculate impedance based on the AC current and the AC voltage, and determine a magnitude of a magnetic field based on the impedance; and a positioning unit configured to support the giant magneto-impedance probe and position the giant magneto-impedance probe to a predetermined position, wherein when the positioning unit positions the giant magneto-impedance probe at a first position near a surface of an object to be measured, the measurement circuit measures a first AC voltage of the giant magneto-impedance probe, and the calculation unit calculates a first magnetic field based on the first AC voltage; when the positioning unit positions the giant magneto-impedance probe at a second position above the first position, the measurement circuit measures a second AC voltage of the giant magneto-impedance probe, and the calculation unit calculates a second magnetic field based on the second AC voltage, and calculates a measurement magnetic field at the first position near the surface of the object to be measured based on the first magnetic field and the second magnetic field.

In an example of the magnetic field detection device, the positioning unit positions the giant magneto-impedance probe perpendicular to the surface of the object to be measured, and the second position is located vertically above the first position.

In an example of the magnetic field detection device, the calculation unit calculates the measurement magnetic field at the first position near the surface of the object to be measured based on a following formula: Hₜᵢₚ=(H₁−H₂)*L ΔZ, where Hₜᵢₚ is the measurement magnetic field at the first position near the surface of the object to be measured; H₁ is the first magnetic field; H₂ is the second magnetic field; L is an effective length of the giant magneto-impedance probe, and ΔZ is a distance between the second position and the first position.

In an example of the magnetic field detection device, a distance between the second position and the first position is in a range of 1 μm to 2 mm, preferably in a range of 10 μm to 1 mm; and the effective length of the giant magneto-impedance probe is in a range of 1 mm to 3 cm, preferably in a range of 3 mm to 2 cm.

In an example of the magnetic field detection device, the positioning unit is further configured to move the giant magneto-impedance probe along the surface of the object to be measured, to measure magnetic fields at multiple positions.

In an example of the magnetic field detection device, the magnetic field detection device further comprises a control unit configured to control one or more of the AC signal source, the measurement circuit, the calculation unit, and the positioning unit, to automatically measure the magnetic fields at multiple positions on the surface of the object to be measured.

In another embodiments, a magnetic field measurement method comprises: positioning a giant magneto-impedance probe at a first position near a surface of an object to be measured; applying an AC current to the giant magneto-impedance probe and measuring a first AC voltage of the probe; calculating impedance of the giant magneto-impedance probe based on the AC current and the first AC voltage, and determining a first magnetic field based on the impedance; positioning the giant magneto-impedance probe at a second position above the first position; applying the AC current to the giant magneto-impedance probe and measuring a second AC voltage of the probe; calculating impedance of the giant magneto-impedance probe based on the AC current and the second AC voltage, and determining a second magnetic field based on the impedance; calculating a measurement magnetic field at the first position near the surface of the object to be measured based on the first magnetic field and the second magnetic field.

In an example of the magnetic field measurement method, the giant magneto-impedance probe is positioned perpendicular to the surface of the object to be measured, and the second position is located vertically above the first position.

In an example of the magnetic field measurement method, the measurement magnetic field at the first position near the surface of the object to be measured is calculated based on a following formula: Hₜᵢₚ=(H₁−H₂)*L/ΔZ, where Hₜᵢₚ is the measurement magnetic field at the first position near the surface of the object to be measured; H₁ is the first magnetic field; H₂ is the second magnetic field; L is an effective length of the giant magneto-impedance probe; and ΔZ is a distance between the second position and the first position.

In an example of the magnetic field measurement method, the method further comprises: moving the giant magneto-impedance probe along the surface of the object to be measured, to measure magnetic fields at multiple positions.

In an embodiment, a magnetic field detection device comprises: a vibrating head on which a giant magneto-impedance GMI probe is mounted; an alternating current AC signal source configured to apply an AC current having a first frequency to the GMI probe; a vibration controller configured to control the vibrating head to vibrate at a second frequency based on a reference signal having a second frequency; a measurement circuit configured to measure an AC voltage signal at the first frequency provided by the GMI probe when the AC current at the first frequency is applied to the GMI probe, and generate a measurement signal indicating an amplitude of the AC voltage signal; an interlock circuit configured to extract the amplitude of the measurement signal based on the reference signal at the second frequency and provide the reference signal at the second frequency to the vibration controller; and a calculation unit configured to determine a magnitude of a magnetic field measured by the GMI probe based on the amplitude of the measurement signal.

In an example of the magnetic field detection device, a distance measuring probe is further mounted on the vibrating head, and the vibration controller receives a distance measuring signal provided by the distance measuring probe and adjusts a vibration frequency and amplitude of the vibrating head based on the distance measuring signal.

In an example of the magnetic field detection device, the vibrating head includes a piezoelectric material that deforms in response to a voltage applied thereto to generate vibration without producing a magnetic field.

In an example of the magnetic field detection device, the AC signal source comprises: a clock circuit configured to generate a clock signal having the first frequency; and a driving circuit configured to generate the AC current having the first frequency based on the clock signal and provide the AC current to the GMI probe, wherein the clock signal at the first frequency is further provided to the measurement circuit.

In an example of the magnetic field detection device, the vibration controller comprises: a lock-in amplifier configured to extract an amplitude and phase of the distance measuring signal provided by the distance measuring probe based on the reference signal at the second frequency received from the interlock circuit; and a driving circuit configured to control an amplitude and frequency of a driving voltage signal provided to the vibrating head based on the amplitude and phase of the distance measuring signal, thereby causing the vibrating head to vibrate at a desired amplitude and frequency.

In an example of the magnetic field detection device, the measurement circuit comprises: a capacitor, configured to filter out a DC component in the AC voltage signal, one plate of which is connected to a measurement terminal of the GMI probe providing the AC voltage signal; a phase adjustment circuit, an input terminal of which is connected to the other plate of the capacitor, configured to adjust a phase of the AC voltage signal filtered by the capacitor such that the filtered AC voltage signal and the clock signal from the clock circuit have the same phase; a lock-in amplifier connected to an output terminal of the phase adjustment circuit, configured to extract the amplitude of the AC voltage signal based on the clock signal and output the measurement signal indicating the amplitude of the AC voltage signal; and a voltage-to-current conversion circuit configured to generate a current signal based on a voltage of the measurement signal and provide the current signal to the measurement terminal of the GMI probe to at least partially offset the magnetic field detected by the GMI probe, thereby serving to bias the GMI probe at a more sensitive operating point.

In an example of the magnetic field detection device, the interlock circuit includes a lock-in amplifier that generates the reference signal having the second frequency and extracts the amplitude of the measurement signal provided by the measurement circuit based on the reference signal.

In an embodiment, a magnetic field detection device comprises: a vibrating head on which a first GMI probe and a second GMI probe are mounted, the second GMI probe being located at a higher height than the first GMI probe; an AC signal source configured to apply an AC current having a first frequency to the GMI probes; a vibration controller configured to control the vibrating head to vibrate at a second frequency based on a reference signal having the second frequency; a first measurement circuit configured to measure a first AC voltage signal provided by the first GMI probe and generate a first measurement signal indicating an amplitude of the first AC voltage signal; a second measurement circuit configured to measure a second AC voltage signal provided by the second GMI probe and generate a second measurement signal indicating an amplitude of the second AC voltage signal; a differential amplifier configured to generate a measurement signal indicating a difference between the first measurement signal and the second measurement signal; an interlock circuit configured to extract an amplitude of the measurement signal based on the reference signal of the second frequency and provide the reference signal to the vibration controller; and a calculation unit configured to determine a magnitude of the measured magnetic field based on the amplitude of the measurement signal.

In an example of the magnetic field detection device, a distance measuring probe is further mounted on the vibrating head, and the vibration controller receives a distance measuring signal provided by the distance measuring probe and adjusts a vibration frequency and amplitude of the vibrating head based on the distance measuring signal.

In an example of the magnetic field detection device, the vibrating head includes a piezoelectric material that has no magnetic remanence itself and deforms in response to a voltage applied thereto to generate vibration.

In an example of the magnetic field detection device, the AC signal source comprises: a clock circuit configured to generate a clock signal having the first frequency; and a driving circuit configured to generate the AC current having the first frequency based on the clock signal and provide the AC current to the first GMI probe and the second GMI probe, wherein the clock signal of the first frequency is further provided to the first measurement circuit and the second measurement circuit.

In an example of the magnetic field detection device, the vibration controller comprises: a lock-in amplifier configured to extract an amplitude and phase of the distance measuring signal provided by the distance measuring probe based on the reference signal of the second frequency received from the interlock circuit; and a driving circuit configured to control an amplitude and frequency of a driving voltage signal provided to the vibrating head based on the amplitude and phase of the distance measuring signal, thereby causing the vibrating head to vibrate at a desired amplitude and frequency.

In an example of the magnetic field detection device, the first measurement circuit comprises: a first capacitor, configured to filter out a DC component in the first AC voltage signal, one plate of which is connected to a measurement terminal of the first GMI probe providing the first AC voltage signal; a first phase adjustment circuit, an input terminal of which is connected to the other plate of the first capacitor, configured to adjust a phase of the first AC voltage signal filtered by the first capacitor such that the filtered first AC voltage signal and the clock signal provided by the clock circuit have the same phase; a first lock-in amplifier connected to an output terminal of the first phase adjustment circuit, configured to extract the amplitude of the first AC voltage signal based on the clock signal and output the first measurement signal indicating the amplitude of the first AC voltage signal; and a first voltage-to-current conversion circuit configured to generate a first current signal based on a voltage of the first measurement signal and provide the first current signal to the measurement terminal of the first GMI probe to at least partially offset the magnetic field detected by the first GMI probe, thereby serving to bias the first GMI probe at a more sensitive operating point; and
the second measurement circuit comprises: a second capacitor, configured to filter out a DC component in the second AC voltage signal, one plate of which is connected to a measurement terminal of the second GMI probe providing the second AC voltage signal; a second phase adjustment circuit, an input terminal of which is connected to the other plate of the second capacitor, configured to adjust a phase of the second AC voltage signal filtered by the second capacitor such that the filtered second AC voltage signal and the clock signal provided by the clock circuit have the same phase; a second lock-in amplifier connected to an output terminal of the second phase adjustment circuit, configured to extract the amplitude of the second AC voltage signal based on the clock signal and output the second measurement signal indicating the amplitude of the second AC voltage signal; and a second voltage-to-current conversion circuit configured to generate a second current signal based on a voltage of the second measurement signal and provide the second current signal to the measurement terminal of the second GMI probe to at least partially offset the magnetic field detected by the second GMI probe, thereby serving to bias the second GMI probe at a more sensitive operating point.

In an example of the magnetic field detection device, the interlock circuit includes a lock-in amplifier that generates the reference signal having the second frequency and extracts the amplitude of the measurement signal provided by the differential amplifier based on the reference signal.

In an example of the magnetic field detection device, the differential amplifier is a proportion-adjustable differential amplifier calibrated such that, when no magnetic field is present or when the first GMI probe and the second GMI probe are in the same magnetic field, the measurement signal output by the proportion-adjustable differential amplifier indicates a zero difference between the first measurement signal and the second measurement signal.

Unless the context clearly requires otherwise, throughout the description and the claims, the words “include”, “including”, “comprise”, “comprising” and the like are to be construed in an inclusive sense, as opposed to an exclusive or exhaustive sense; that is to say, in the sense of “comprising, but is not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the description using the singular or plural number may also comprise the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments comprise, while other embodiments do not comprise, certain features, elements and/or states. Thus, such conditional language is not generally intended to imply that features, elements and/or states are in any way required for one or more embodiments or that one or more embodiments necessarily comprise logic for deciding, with or without author input or prompting, whether these features, elements and/or states are comprised or are to be performed in any particular embodiment.

While some embodiments have been described, these embodiments have been presented by way of example, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each one of these blocks may be implemented in a variety of different ways. The order of these blocks may also be changed. Any suitable combination of the elements and actions of some embodiments described above can be combined to provide further embodiments. The accompanying claims and their equivalents are intended to cover such forms or modifications as would fall within the scope and spirit of the disclosure.

Thus far, the technical solution of the present disclosure has been described in conjunction with the preferred implementations shown in the accompanying drawings. However, it is easy for those skilled in the art to understand that obviously the scope of protection of the present disclosure is not limited to these specific embodiments. Without departing from the principles of the present disclosure, those skilled in the art may make equivalent modifications or substitutions to the relevant technical features, and the technical solutions resulted from these modifications or substitutions will fall within the scope of protection of the present disclosure.

The above description has been provided for the purpose of illustration and description. Furthermore, this description is not intended to limit the embodiments of the present disclosure to the form disclosed herein. Although multiple example aspects and embodiments have been discussed above, those skilled in the art will recognize certain variations, modifications, alterations, additions, and sub combinations thereof.

What is claimed is:

1. A magnetic field detection device comprising:
a giant magneto-impedance probe;
an AC signal source configured to apply an AC current to the giant magneto-impedance probe;
a measurement circuit configured to measure an AC voltage on the giant magneto-impedance probe;
a calculation unit configured to calculate impedance based on the AC current and the AC voltage, and determine a magnitude of a magnetic field based on the impedance; and
a positioning unit configured to support the giant magneto-impedance probe and position the giant magneto-impedance probe to a predetermined position,
wherein when the positioning unit positions the giant magneto-impedance probe at a first position near a surface of an object to be measured, the measurement circuit measures a first AC voltage of the giant magneto-impedance probe, and the calculation unit calculates a first magnetic field based on the first AC voltage; when the positioning unit positions the giant magneto-impedance probe at a second position above the first position, the measurement circuit measures a second AC voltage of the giant magneto-impedance probe, and the calculation unit calculates a second magnetic field based on the second AC voltage, and calculates a measurement magnetic field at the first position near the surface of the object to be measured based on the first magnetic field and the second magnetic field.

2. The magnetic field detection device of claim 1, wherein the positioning unit positions the giant magneto-impedance probe perpendicular to the surface of the object to be measured, and the second position is located vertically above the first position.

3. The magnetic field detection device of claim 1, wherein the calculation unit calculates the measurement magnetic field at the first position near the surface of the object to be measured based on a following formula:
$${H}_{tip} = ( {H}_{1} - {H}_{2} ) * L / Δ Z ,$$
where Hₜᵢₚ is the measurement magnetic field at the first position near the surface of the object to be measured; H₁ is the first magnetic field; H₂ is the second magnetic field; L is an effective length of the giant magneto-impedance probe, and ΔZ is a distance between the second position and the first position.

4. The magnetic field detection device of claim 1, wherein the positioning unit is further configured to move the giant magneto-impedance probe along the surface of the object to be measured, to measure magnetic fields at multiple positions.

5. The magnetic field detection device of claim 1, further comprising a control unit configured to control one or more of the AC signal source, the measurement circuit, the calculation unit, and the positioning unit, to automatically measure the magnetic fields at multiple positions on the surface of the object to be measured.

6. A magnetic field measurement method comprising:
positioning a giant magneto-impedance probe at a first position near a surface of an object to be measured;
applying an AC current to the giant magneto-impedance probe and measuring a first AC voltage of the probe;
calculating impedance of the giant magneto-impedance probe based on the AC current and the first AC voltage, and determining a first magnetic field based on the impedance;
positioning the giant magneto-impedance probe at a second position above the first position;
applying the AC current to the giant magneto-impedance probe and measuring a second AC voltage of the probe;
calculating impedance of the giant magneto-impedance probe based on the AC current and the second AC voltage, and determining a second magnetic field based on the impedance;
calculating a measurement magnetic field at the first position near the surface of the object to be measured based on the first magnetic field and the second magnetic field.

7. The method of claim 6, wherein the giant magneto-impedance probe is positioned perpendicular to the surface of the object to be measured, and the second position is located vertically above the first position.

8. The magnetic field detection device of claim 6, wherein the measurement magnetic field at the first position near the surface of the object to be measured is calculated based on a following formula:
$${H}_{tip} = ( {H}_{1} - {H}_{2} ) * L / Δ Z ,$$
where Hₜᵢₚ is the measurement magnetic field at the first position near the surface of the object to be measured; H₁ is the first magnetic field; H₂ is the second magnetic field; L is an effective length of the giant magneto-impedance probe; and ΔZ is a distance between the second position and the first position.

9. A magnetic field detection device, comprising:
a vibrating head on which a giant magneto-impedance GMI probe is mounted;
an alternating current AC signal source configured to apply an AC current having a first frequency to the GMI probe;
a vibration controller configured to control the vibrating head to vibrate at a second frequency based on a reference signal having a second frequency;
a measurement circuit configured to measure an AC voltage signal at the first frequency provided by the GMI probe when the AC current at the first frequency is applied to the GMI probe, and generate a measurement signal indicating an amplitude of the AC voltage signal;
an interlock circuit configured to extract the amplitude of the measurement signal based on the reference signal at the second frequency and provide the reference signal at the second frequency to the vibration controller; and
a calculation unit configured to determine a magnitude of a magnetic field measured by the GMI probe based on the amplitude of the measurement signal.

10. The magnetic field detection device of claim 9, wherein a distance measuring probe is further mounted on the vibrating head, and the vibration controller receives a distance measuring signal provided by the distance measuring probe and adjusts a vibration frequency and amplitude of the vibrating head based on the distance measuring signal.

11. The magnetic field detection device of claim 9, wherein the vibrating head includes a piezoelectric material that deforms in response to a voltage applied thereto to generate vibration without producing a magnetic field.

12. The magnetic field detection device of claim 9, wherein the AC signal source comprises:
a clock circuit configured to generate a clock signal having the first frequency; and
a driving circuit configured to generate the AC current having the first frequency based on the clock signal and provide the AC current to the GMI probe,
wherein the clock signal at the first frequency is further provided to the measurement circuit.

13. The magnetic field detection device of claim 10, wherein the vibration controller comprises:
a lock-in amplifier configured to extract an amplitude and phase of the distance measuring signal provided by the distance measuring probe based on the reference signal at the second frequency received from the interlock circuit; and
a driving circuit configured to control an amplitude and frequency of a driving voltage signal provided to the vibrating head based on the amplitude and phase of the distance measuring signal, thereby causing the vibrating head to vibrate at a desired amplitude and frequency.

14. The magnetic field detection device of claim 12, wherein the measurement circuit comprises:
a capacitor, configured to filter out a DC component in the AC voltage signal, one plate of which is connected to a measurement terminal of the GMI probe providing the AC voltage signal;
a phase adjustment circuit, an input terminal of which is connected to the other plate of the first capacitor, configured to adjust a phase of the AC voltage signal filtered by the first capacitor such that the filtered AC voltage signal and the clock signal provided by the clock circuit have the same phase;
a lock-in amplifier connected to an output terminal of the first phase adjustment circuit, configured to extract the amplitude of the AC voltage signal based on the clock signal and output the measurement signal indicating the amplitude of the AC voltage signal; and
a voltage-to-current conversion circuit configured to generate a current signal based on a voltage of the measurement signal and provide the current signal to the measurement terminal of the GMI probe to at least partially offset the magnetic field detected by the GMI probe, thereby serving to bias the GMI probe at a more sensitive operating point.

15. The magnetic field detection device of claim 9, wherein the interlock circuit includes a lock-in amplifier that generates the reference signal having the second frequency and extracts the amplitude of the measurement signal provided by the measurement circuit based on the reference signal.

16. The magnetic field detection device of claim 9, wherein the GMI probe includes a first GMI probe and a second GMI probe, which is located at a higher height than the first GMI probe; and
the measurement circuit comprises a first measurement circuit configured to measure a first AC voltage signal provided by the first GMI probe and generate a first measurement signal indicating an amplitude of the first AC voltage signal; and a second measurement circuit configured to measure a second AC voltage signal provided by the second GMI probe and generate a second measurement signal indicating an amplitude of the second AC voltage signal;
wherein the magnetic field detection device further comprises a differential amplifier configured to generate a measurement signal indicating a difference between the first measurement signal and the second measurement signal.

17. The magnetic field detection device of claim 16, wherein the AC signal source comprises:
a clock circuit configured to generate a clock signal having the first frequency; and
the driving circuit is further configured to generate the AC current having the first frequency based on the clock signal and provide the AC current to the first GMI probe and the second GMI probe, and
wherein the clock signal of the first frequency is further provided to the first measurement circuit and the second measurement circuit.

18. The magnetic field detection device of claim 17, wherein the first measurement circuit comprises:
a first capacitor, configured to filter out a DC component in the first AC voltage signal, one plate of which is connected to a measurement terminal of the first GMI probe providing the first AC voltage signal;
a first phase adjustment circuit, an input terminal of which is connected to the other plate of the first capacitor, configured to adjust a phase of the first AC voltage signal filtered by the first capacitor such that the filtered first AC voltage signal and the clock signal provided by the clock circuit have the same phase;
a first lock-in amplifier connected to an output terminal of the first phase adjustment circuit, configured to extract the amplitude of the first AC voltage signal based on the clock signal and output the first measurement signal indicating the amplitude of the first AC voltage signal; and
a first voltage-to-current conversion circuit configured to generate a first current signal based on a voltage of the first measurement signal and provide the first current signal to the measurement terminal of the first GMI probe to at least partially offset the magnetic field detected by the first GMI probe, thereby biasing the first GMI probe at a more sensitive operating point; and
the second measurement circuit comprises:
a second capacitor, configured to filter out a DC component in the second AC voltage signal, one plate of which is connected to a measurement terminal of the second GMI probe providing the second AC voltage signal;
a second phase adjustment circuit, an input terminal of which is connected to the other plate of the second capacitor, configured to adjust a phase of the second AC voltage signal filtered by the second capacitor such that the filtered second AC voltage signal and the clock signal provided by the clock circuit have the same phase;
a second lock-in amplifier connected to an output terminal of the second phase adjustment circuit, configured to extract the amplitude of the second AC voltage signal based on the clock signal and output the second measurement signal indicating the amplitude of the second AC voltage signal; and
a second voltage-to-current conversion circuit configured to generate a second current signal based on a voltage of the second measurement signal and provide the second current signal to the measurement terminal of the second GMI probe to at least partially offset the magnetic field detected by the second GMI probe, thereby serving to bias the second GMI probe at a more sensitive operating point.

19. The magnetic field detection device of claim 16, wherein the interlock circuit includes a lock-in amplifier that generates the reference signal having the second frequency and extracts the amplitude of the measurement signal provided by the differential amplifier based on the reference signal.

20. The magnetic field detection device of claim 16, wherein the differential amplifier is a proportion-adjustable differential amplifier calibrated such that, when no magnetic field is present or when the first GMI probe and the second GMI probe are in the same magnetic field, the measurement signal output by the proportion-adjustable differential amplifier indicates a zero difference between the first measurement signal and the second measurement signal.
